(19) United States
(12) Patent Application Publication
(10) Pub. No.: US 2008/0217640 A1
(43) Pub. Date: Sep. 11, 2008

(54) Semiconductor Light emitting device, LED package using the same, and method for fabricating the same

(75) Inventors: Naoto Suzuki, Tokyo (JP); Yoshihiro Nakamura, Tokyo (JP); Yoshiaki Yasuda, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 12/075,245

(22) Filed: Mar. 10, 2008

(30) Foreign Application Priority Data
Mar. 8, 2007 (JP) 2007-058644

(51) Int. Cl. H01L 33/00; H01L 21/00

(52) U.S. Cl. 257/98; 257/99; 438/29; 257/E33.001

(57) ABSTRACT

A semiconductor light emitting device is provided which can prevent the reflectance of a metal film from deteriorating due to heat aging and can prevent wire bonding performance of the semiconductor light emitting element from deteriorating due to the diffusion of Ni contained in a Ni barrier metal layer to the reflection layer during die-bonding of the semiconductor light emitting element. The semiconductor light emitting device includes a metal film formed on a substrate and a semiconductor light emitting element. The metal film includes a barrier metal layer configured to prevent a predetermined material from being diffused into the substrate, a metal layer formed on the barrier metal layer; and a reflection layer formed on the metal layer. The reflection layer is configured to reflect light emitted from the semiconductor light emitting element, and the metal layer is made of Ti or Pd.

This application claims the priority benefit under 35 U.S.C. §119 of Japanese Patent Application No. 2007-058644 filed on Mar. 8, 2007, which is hereby incorporated in its entirety by reference.

### BACKGROUND OF THE INVENTION

1. Field of the Invention

The present invention to a semiconductor light emitting device, an LED package using the same, and a method for fabricating the same.

2. Description of the Related Art

Conventionally, semiconductor light emitting devices using an LED as a light emitting element are now used prevailingly. In such a device, the optical output efficiency and durability are required to be improved further. As an example of a semiconductor light emitting device, an LED package is disclosed in Japanese patent application Laid-Open No. 2005-277380 (corresponding to U.S. Application Publication No. US 2006/0001055 A1, both of which are hereby incorporated by reference in their entireties). The LED package has a horn formed by anisotropically etching a silicon (Si) wafer and a metal film for supplying power to a light emitting element placed within the horn. The metal film deposited in the horn is used not only for power supply, but also for serving as a reflection film for efficiently directing light emitted from the light emitting element to the outside.

In this technique, the metal film deposited in the horn is composed of: an insulating film made of a silicon dioxide (SiO₂) film formed on the surface of the Si wafer; an adhesion layer made of titanium (Ti), chromium (Cr), or the like, and formed on the silicon dioxide film; a barrier metal layer formed on the adhesion layer and made of nickel (Ni), or the like, for preventing gold (Au)-tin (Sn) eutectic bonding material or solder bonding material from diffusing into the Si wafer; and an uppermost reflection layer having a high reflectance. The metal film configured in this manner can efficiently guide light from an LED to the outside.

The metal film deposited in the horn of the silicon substrate can be partly etched or lifted off to be formed into an electrode pattern. Accordingly, the metal film deposited in the horn can be used not only as a reflection film, but also for electrodes.

In more detail, for example, the same assignee as that of the present application has proposed some techniques disclosed in Japanese patent application Laid-Open No. 2007-194385 (corresponding to U.S. Application Publication No. US 2007/0181900 A1, both of which are hereby incorporated by reference in their entireties), and in Japanese Patent Application Nos. 2006-334623 and 2006-339511, the entire contents of both of which are incorporated herein by reference. According to one such technique, the metal film formed in the semiconductor light emitting device is composed of a Ti film serving as an adhesion layer with a thermal oxidation layer, an Ni film serving as a barrier metal layer, and an Ag or Ag alloy film serving as a reflection layer, which are consecutively deposited in this order. The Ag alloy for use in the reflection layer may desirably contain Bi in the amount of 0.05 atomic % to 0.15 atomic % in view of the required durability, and may desirably further contain at least one element selected from Au, Pd, Cu, Pt, and Nd in an amount greater than Bi.

A semiconductor light emitting element such as an LED is die-bonded to the silicon substrate provided with such a metal film, and the semiconductor light emitting element is then electrically connected to electrodes by wire-bonding or via bumps. Then, a resin seal is applied, thereby completing the semiconductor light emitting device. In this instance, a blue semiconductor light emitting element is, for example, sealed within a horn using a transparent resin in which a wavelength converting material such as a fluorescent material is dispersed, thereby completing a white semiconductor light emitting device.

It should be noted that among other metals Ag has the highest reflectance within the visible light range. Accordingly, Ag is the most suitable metal for use as the reflection layer of a semiconductor light emitting device. However, Ag is chemically active and aggregates when heat is applied. When this occurs, the Ag crystalline particles adversely coarsen with ease. Accordingly, when compounding an Ag alloy, another element is added thereto, to improve its heat resistance. However, adding another element cannot perfectly prevent the decrease in reflectance due to heat. Even when an Ag alloy is used to form a reflection layer of an LED light emitting device, repeated operations can significantly decrease the reflectance of the Ag alloy, thereby causing possible problems such as decreased luminous flux, color heterogeneity, and the like.

As described above, the semiconductor light emitting element (such as an LED element) may be die-bonded to the silicon substrate using an Au—Sn eutectic solder material or an Sn—Ag—Cu soldering material. In this case, a barrier metal layer made of Ni, for example, is inserted in between the adhesion layer and the reflection layer, to serve as a diffusion barrier layer for the molten solder components. When a semiconductor light emitting element is die-bonded using an Sn—Ag—Cu solder material, the thickness of the Ni barrier metal layer is preferably 0.5 μm or more. When a semiconductor light emitting element is die-bonded using an Au—Sn eutectic solder material, the thickness of the Ni barrier metal layer is preferably 0.1 μm or more. When the Ni barrier metal layer is present, however, Ni contained in the barrier metal layer is diffused to the surface of the reflection layer during die-bonding, thereby forming a Ni oxide. This may reduce the bonding performance when wire-bonding, which may cause the wire bonding portion to peel off due to thermal stress generated by repeatedly supplying power. If this occurs, it is assumed that a problem may occur in which the LED is not lit due to disconnection.

### SUMMARY OF THE INVENTION

In view of the foregoing problems, one object of the present invention is to provide a semiconductor light emitting device which can prevent the reflectance of a metal film (which is a reflection layer) from deteriorating due to heat aging, and which can prevent wire bonding performance of the semiconductor light emitting element (for example, an LED element) from deteriorating due to the diffusion of Ni contained in the Ni barrier metal layer to the reflection layer during die-bonding of the semiconductor light emitting element.

In accordance with one aspect of the present invention, a semiconductor light emitting device includes: a substrate; a metal film deposited on the substrate; and a semiconductor light emitting element. The metal film includes: a barrier metal layer configured to prevent a predetermined material from being diffused into the substrate; a metal layer consisting essentially of Ti or Pd; and a reflection layer configured to reflect light emitted from the semiconductor light emitting element, which are deposited from the substrate in this order.

In the semiconductor light emitting device as described above, the barrier metal layer may consist essentially of Ni.

Furthermore, in the semiconductor light emitting device as described above, the reflection layer may consist essentially of Ag or an Ag alloy.

In the semiconductor light emitting device as described above, the Ag alloy can contain at least one element selected from the group consisting of Bi, At, Pd, Cu, Pt, and Nd.

In the semiconductor light emitting device as described above, the barrier metal layer may consist essentially of Ni, the reflection layer may consist essentially of Ag or an Ag alloy, and the metal layer may consist essentially of Ti and have a thickness in the range of 0.35 nm to 200 nm.

In the semiconductor light emitting device as described above, the barrier metal layer may consist essentially of Ni, the reflection layer may consist essentially of Ag or an Ag alloy, and the metal layer may consist essentially of Pd and have a thickness in the range of 1 nm to 1000 nm.

In the semiconductor light emitting device as described above, the substrate can have a surface defined by a bottom surface having a (100) plane and slanted side walls having a (111) plane, and the metal film can be formed at least on the bottom surface and the slanted side walls.

In accordance with another aspect of the present invention, an LED package includes: a housing; a lead frame provided along the housing and having a pair of leads; and the semiconductor light emitting device described above. The semiconductor light emitting device is mounted on at least part of the lead frame to electrically connect the semiconductor light emitting device to the pair of leads.

In the LED package as described above, the housing may have a recess in which the semiconductor light emitting device is mounted, and a sealing resin can be filled in the recess to seal the semiconductor light emitting device. In this case, the sealing resin can contain a wavelength converting material.

In accordance with still another aspect of the present invention, a method for fabricating a semiconductor light emitting device includes: (a) forming a barrier metal layer made of Ni on a silicon substrate; (b) forming a metal layer of Ti or Pd on the barrier metal layer; (c) forming a reflection layer made of Ag or an Ag alloy on the metal layer; and (d) electrically connecting a semiconductor light emitting element to the reflection layer.

The present invention as described above can prevent the reflectance of a metal film (being a reflection layer) from deteriorating due to heat aging. The present invention can also prevent wire bonding performance of the semiconductor light emitting element (for example, an LED element) from deteriorating due to the diffusion of Ni contained in the Ni barrier metal layer to the reflection layer during die-bonding of the semiconductor light emitting element.

### BRIEF DESCRIPTION OF THE DRAWINGS

These and other characteristics, features, and advantages of the present invention will become clear from the following description with reference to the accompanying drawings, wherein:

FIG. 1 is a diagram illustrating a structural example of a semiconductor light emitting device made in accordance with principles of the present invention;

FIG. 2 is a diagram illustrating a more concrete structural example of a semiconductor light emitting device made in accordance with principles of the present invention;

FIG. 3 is a schematic view illustrating an LED package in which an LED chip is mounted using a plate submount;

FIG. 4 is a cross-sectional view showing the detailed structure of the silicon submount of FIG. 3;

FIG. 5 is a diagram illustrating a structural example of a semiconductor light emitting device;

FIG. 6 is a diagram illustrating an LED package in which an LED chip is mounted using a submount having a horn;

FIG. 7 is a cross-sectional view showing the silicon submount of FIG. 6;

FIGS. 8A through 8H show process steps for fabricating a submount;

FIGS. 9A through 9C show process steps for fabricating a semiconductor light emitting device;

FIG. 10 is a graph showing the relationship between the thickness of a Ti metal layer and the reflectance of a submount at the reflecting layer of 460 nm before and after heat aging;

FIG. 11 is a graph showing the relationship between the thickness of a Ti metal layer and the reflectance of the reflecting layer at a wavelength of 460 nm before and after heat aging;

FIG. 12 is a graph showing the relationship between the thickness of a Pd metal layer and the reflectance of the reflecting layer at a wavelength of 460 nm before and after heat aging;

FIG. 13 is a graph showing the relationship between the thickness of a Pd metal layer and the reflectance of the reflecting layer at a wavelength of 460 nm before and after heat aging;

FIG. 14 is a graph showing the results of a wire-pulling strength test when the metal film in the light emitting device includes a Ti metal layer;

FIG. 15 is a graph showing the results of a wire-pulling strength test when the metal film in the light emitting device includes a Pd metal layer;

FIG. 16A is a graph showing vertical reflectances of Ag—Bi(0.07 at. %)-Nd with respect to a lapsed time, and FIG. 16B is a graph showing vertical reflectances of Ag—Bi(0.14 at. %)-Nd with respect to a lapsed time;

FIG. 17 is a graph showing initial vertical reflectances of five types of Ag—Bi based alloy samples;

FIG. 18 is a graph showing a dependency of the reflectance of a Ag—Bi based alloy on the atmospheric pressure during deposition;

FIG. 19 is a diagram showing a usage of an LED package; and

FIG. 20 is a diagram illustrating another concrete structural example of a semiconductor light emitting device made in accordance with principles of the present invention.

### DETAILED DESCRIPTION

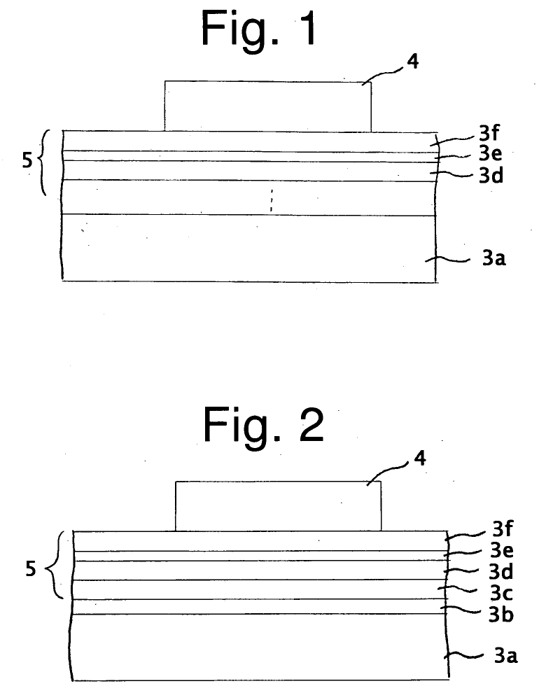

FIG. 1 is a diagram illustrating a structural example of a semiconductor light emitting device according to one embodiment of the present invention. As shown in FIG. 1, the semiconductor light emitting device, such as an LED package, an LED lamp, or the like, can include a substrate such as a silicon substrate 3a, a metal film 5 deposited on the substrate 3a, and a semiconductor light emitting element 4, such as an LED chip, or the like. The metal film 5 can include a barrier metal layer 3d, a metal layer 3e, and a reflection layer 3f formed in this order. The barrier metal layer 3d can function to prevent the diffusion of a predetermined material to the substrate 3a. The reflection layer 3f can function as a reflection surface for reflecting the light emitted from the semiconductor light emitting element 4. The metal layer 3e may be made of Ti or Pd.

In this instance, the semiconductor light emitting element 4 and the metal film 5 can be electrically connected. Specifically, as described later, the semiconductor light emitting element 4 and the reflection layer 3f of the metal film 5 can be electrically connected. In this case, the metal film 5 (specifically, the reflection layer 3f thereof) can function as a reflection film and as an electrode for the semiconductor light emitting element 4.

FIG. 2 shows a more detailed configuration example of the semiconductor light emitting device according to an embodiment of the present invention. As shown in FIG. 2, the semiconductor light emitting device can include a substrate 3a, such as a silicon substrate, an insulating film 3b, such as a silicon dioxide film, formed on the surface of the substrate 3a, a metal film 5 formed on the insulating film 3b, and a semiconductor light emitting element 4 such as an LED chip. The metal film 5 can include an adhesion layer 3c for achieving the adhesion with the insulating film 3b, a barrier metal layer 3d for preventing a certain material from diffusing into the substrate 3a, a metal layer 3e, and a reflection layer 3f, which are formed in this order.

Although not shown in FIGS. 1 and 2, the surface of the substrate 3a (such as a silicon substrate) may be formed to have a horn shape. In this instance, the insulation layer 3b, the adhesion layer 3c, the barrier metal layer 3d, the metal layer 3e, and the reflection layer 3f are formed in this order on the surface of the horn shape of the substrate.

In the structural example shown in FIG. 2, the adhesion layer 3c may be made of Ti or a Ti alloy such as a Ti—Ni alloy. In particular, when the adhesion layer 3c is formed of a Ti—Ni alloy, the deterioration of adhesion of the adhesion layer 3c due to heating can be prevented.

In the example shown in FIGS. 1 and 2, the barrier metal layer 3d may be made of Ni to prevent the Au—Sn eutectic solder or other solder material from being diffused to the silicon substrate 3a. The Ni for use in the barrier metal layer 3d may be pure Ni with high purity, but may also be Ni containing some impurities. Specifically, examples of Ni usable as the barrier metal layer 3d include Ni with at least 97% purity.

In the example shown in FIGS. 1 and 2, the metal layer 3e may be made of Ti or Pd. In this instance, when the barrier metal layer 3d is made of Ni, the reflection layer 3f is made of Ag or an Ag alloy, and the metal layer 3e is made of Ti. The thickness of the Ti metal layer 3e is preferably in the range of 0.35 nm to 200 nm. When the metal layer 3e is made of Pd (and the barrier metal layer 3d is made of Ni, and the reflection layer 3f is made of Ag or an Ag alloy), the thickness of the Pd metal layer 3e is preferably in the range of 1 nm to 1000 nm.

In the example shown in FIGS. 1 and 2, the reflection layer 3f may have conductivity in addition to high reflectance. When the reflection layer 3f has conductivity, the semiconductor light emitting element 4 can be electrically connected to the reflection layer 3f. Therefore, the reflection layer 3f can function as an electrode for the semiconductor light emitting element 4 and can function as a reflection film.

Specifically, the reflection layer 3f may be made of Ag or an Ag alloy. More preferably, the reflection layer 3f is made of an Ag alloy. That is, Ag is a metal which has the highest reflectance in the visible range and is suitable for constituting the reflection film (the reflection layer) of the semiconductor light emitting device in terms of superior light output performance. However, Ag is a chemically active metal and can be easily sulfurized or corroded. In addition, Ag can easily aggregate due to heating. An Ag alloy which is prepared by adding another alloying element to Ag can serve as the reflection layer 3f to achieve the reflection function as well as the electrode function. Furthermore, such an Ag alloy has increased corrosion resistance and heat resistance with respect to Ag.

Examples of Ag alloys which may be used for the reflection layer 3f include an alloy containing at least one of Bi, Au, Pd, Cu, Pt, and Nd. More specifically, in terms of durability, preferred examples of the Ag alloy for use as the reflection layer 3f include an Ag alloy containing Bi in the amount of 0.05 to 15 at. % and one element selected from Au, Pd, Cu, Pt, and Nd in an amount greater than the amount of Bi.

A semiconductor light emitting device in accordance with the present invention can be fabricated by, for example, the following process steps: (a) forming an insulating film 3b (such as a silicon dioxide film) on the surface of a substrate 3a (such as a silicon substrate); (b) forming an adhesion layer 3c made of Ti or a Ti alloy (specifically, Ti—Ni alloy) on the insulating film 3b; (c) forming a barrier metal layer 3d made of Ni on the adhesion layer 3c; (d) forming a metal layer 3e made of Ti or Pd on the barrier metal layer 3d; (e) forming a reflection layer 3f made of Ag or an Ag alloy on the metal layer 3e; and (f) electrically connecting a semiconductor light emitting element 4 to the reflection layer 3f.

In this instance, when the adhesion layer 3c is made of an Ti—Ni alloy, for example, it can de deposited by: sputtering using a Ti—Ni alloy target; sputtering from binary compounds using a Ti target and a Ni target; vapor deposition from binary compounds using Ti and Ni materials; alternate deposition of Ti films and Ni films by means of sputtering, vapor deposition, or CVD, followed by thermal alloying; and other means.

Further, the barrier metal layer 3d, the metal layer 3e, and the reflection layer 3f can be formed by vapor deposition or CVD.

Furthermore, the step (a) can include steps of: (a-1) anisotropic etching of the silicon substrate 3a to form a horn defined by a bottom surface having a (100) plane and four slanted side walls having a (111) plane; and (a-2) forming an insulating film 3b on the surface of the silicon substrate 3a with the horn formed thereon. (In other words, a horn may be formed by anisotropic etching of the silicon substrate before the insulating film 3b is formed.) Alternatively, the step (a) can include the steps of: (a-1) anisotropic etching of the silicon substrate 3a to form a horn defined by a bottom surface having the (100) plane and four slanted side walls having the (111) plane; (a-2) anisotropic etching of the slanted side walls of the horn to round the corners of the horn; and (a-3) forming an insulating film 3b on the surface of the silicon substrate 3a with the horn formed thereon. (In other words, a horn may be formed by anisotropic etching of the silicon substrate, and the corners of the horn may be rounded by anisotropic etching of the slanted side walls of the horn, before the insulating film 3b is formed.)

Forming a horn defined by a bottom surface having the (100) plane and four slanted side walls having the (111) plane can be achieved by crystalline anisotropic etching of the crystalline silicon substrate using an alkaline solution of KOH, TMAH, or the like. In this manner, the horn is formed by a bottom surface in parallel with the (100) plane and four slanted side faces having the (111) plane with a slanting angle of 54.7°.

According to the present invention, a metal layer 3e made of Ti or Pd is provided between the barrier metal layer 3d and the reflection layer 3f. In this manner, the deterioration of reflectance of the metal film 5 (specifically, the reflection layer 3f) due to heat aging can be prevented. In addition to this, in the case where the barrier metal layer 3d is made of Ni, Ni may be diffused during die-bonding of the semiconductor light emitting element, thereby lowering the bonding performance of wire bonding. However, with the structure of the present invention, this possible deterioration can be prevented due to the presence of the metal layer 3e.

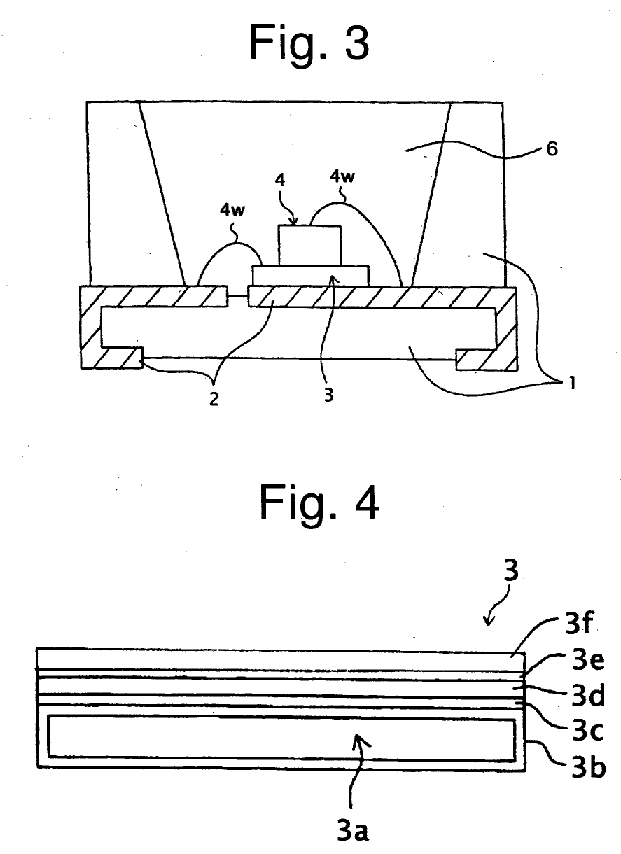

FIG. 3 is a schematic view illustrating an LED package in which a semiconductor light emitting element is mounted using a plate submount. As shown in FIG. 3, a lead frame 2 having two electrical leads is attached to a resin housing 1. A plate silicon submount 3 is placed on one of the leads within the resin housing 1 and die-bonded to the lead using a silver paste.

FIG. 4 is a cross-sectional view showing the detailed structure of the plate silicon submount 3. A silicon substrate 3a is used as the base for forming the plate silicon submount 3. The surface of the silicon substrate 3a is planarized by optical polishing treatment. A silicon dioxide film 3b as an insulating film is formed on the entire surface of the silicon substrate 3a by thermal oxidation in a diffusion furnace. The silicon dioxide film 3b ensures electrical insulation between the silicon submount 3 and the lead even if the silicon submount 3 is die-bonded to the lead. Next, the above-mentioned metal layers 3c, 3d, 3e, and 3f are deposited on the upper surface of the silicon substrate 3a covered with the silicon dioxide-film 3b.

After the silicon submount 3 having the structure described above is die-bonded to one of the leads, a semiconductor light emitting element 4 is die-bonded to the silicon submount 3.

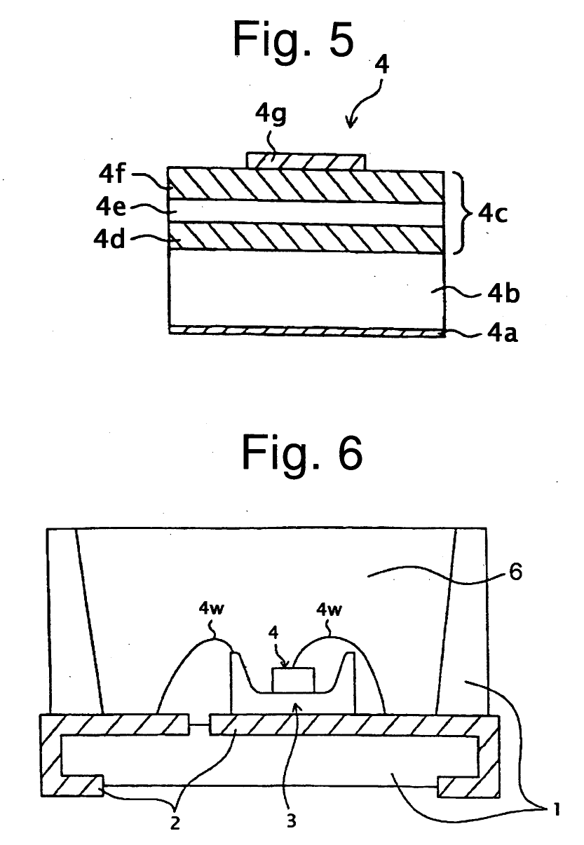

FIG. 5 shows an example of the structure of the semiconductor light emitting element 4. For example, the semiconductor light emitting element 4 is a monochromatic LED emitting substantially monochromatic color light that is red (R), green (G) or blue (B). For example, a semiconductor layer of aluminum gallium arsenide (AlGaAs) is used for a red LED. A semiconductor layer of gallium phosphate (GaP) is used for a green LED. A semiconductor layer of gallium nitride (GaN) is used for a blue LED. For example, for the red LED, as shown in FIG. 5, a semiconductor layer 4c is formed on a gallium arsenide (GaAs) substrate 4b. The semiconductor layer 4c is configured by stacking a p-type semiconductor layer 4d, an emission layer 4e and an n-type semiconductor layer 4f. Metal electrodes 4a and 4g are formed as lowermost and uppermost layers, respectively. For the green LED, a substrate of, for example, GaP is used. Similar to the red LED, for the green LED, a semiconductor layer is stacked upon the GaP substrate, and metal electrodes are formed as lowermost and uppermost layers. The blue LED may have a structure as disclosed in, for example, Japanese Patent Application Laid-Open No. 2006-344682 (in particular, see FIG. 1 and the description on the paragraphs [0017] to [0023]), the entire contents of which are incorporated herein by reference.

As shown in FIG. 3 the lower electrode of the semiconductor light emitting element 4 having the structure described above is die-bonded to the silicon submount 3, the reflection layer 3f of the silicon submount 3 and the lower side of the semiconductor light emitting element 4 can be electrically and mechanically connected together. Then, the reflection layer 3f on the silicon submount 3 which is connected to the lower surface of the semiconductor light emitting element 4 is wire-bonded by a wire 4w to the lead of the lead frame 2 which is not die-bonded to the silicon submount 3. The upper electrode of the semiconductor light emitting element 4 and the lead to which the silicon submount 3 is die-bonded are wire-bonded to each other by another wire 4w. And the inner space of the resin housing 1 is filled with a resin 6 which is transparent or contains phosphor, to complete the LED package.

FIG. 6 is a schematic view showing another example of a structure of an LED package. As shown in FIG. 6, the LED package uses a silicon submount 3 with a horn, and the structure thereof is almost the same as that using the plate silicon submount 3 shown in FIG. 3.

To form the structure shown in FIG. 6, the silicon submount 3 with a horn is die-bonded to one of leads of the lead frame 2. Metal layers 3c, 3d, 3e, and 3f are stacked on the upper surface of the silicon submount 3 with the horn. The semiconductor light emitting element 4 is die-bonded to the bottom surface of the horn of the silicon submount 3 to electrically and mechanically connect the lower surface of the semiconductor light emitting element 4 to the reflecting film on the silicon submount 3. The reflecting film on the surface of the silicon submount 3 electrically connected to the lower surface of the semiconductor light emitting element 4 is wire-bonded by a wire 4w to the lead that is not die-bonded to the silicon submount 3. The upper surface of the semiconductor chip 4 is wire-bonded by another wire 4w to the lead that is die-bonded the silicon submount 3. The inner space of the resin housing 1 is filled with resin 6 which is transparent or contains phosphor, to complete the LED package.

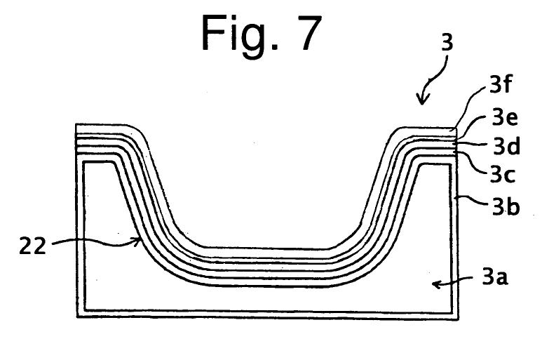

FIG. 7 is a cross-sectional view showing the silicon submount 3 with a horn. A (100) silicon substrate 3a is used as a base for forming the silicon submount 3 with a horn. The surface of the silicon substrate 3a is planarized by optical polishing. First, a horn 22 is formed in the silicon substrate 3a. A silicon dioxide film 3b as an insulating film is formed on the entire surface of the silicon substrate 3a with the horn 22 by thermal oxidation in a diffusion furnace. This structure ensures electrical insulation between the silicon submount 3 and the lead even if the silicon submount 3 is die-bonded to the lead. Next, similar to manner of the forming the plate silicon submount 3, metal layers 3c, 3d, 3e, and 3f are stacked on the upper surface of the silicon substrate 3a covered with the silicon dioxide film 3b.

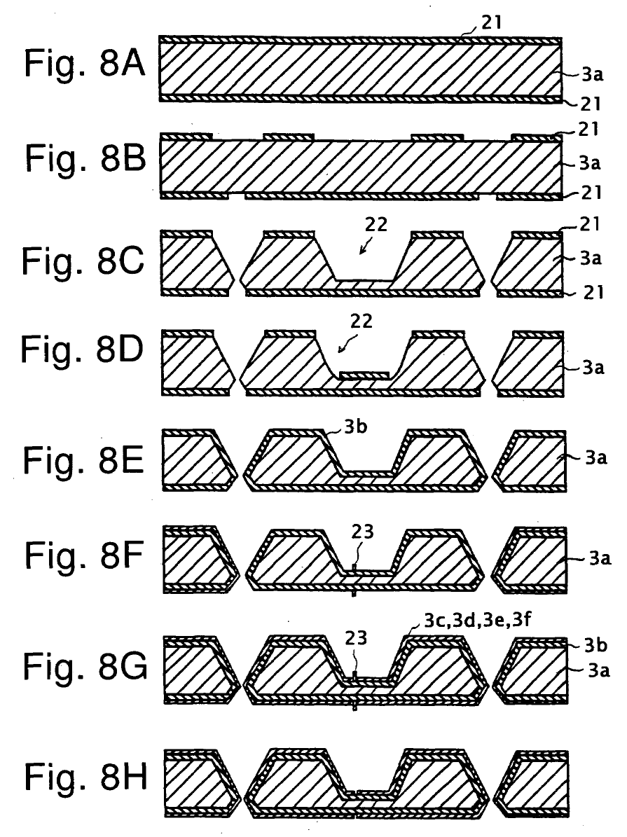

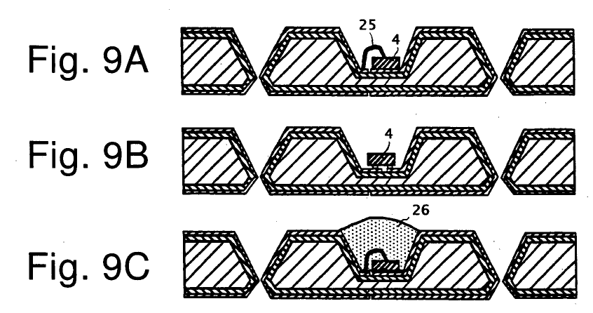

FIGS. 8A through 8H and FIGS. 9A through 9C illustrate an example of the process of fabricating a semiconductor light emitting device made in accordance with the present invention.

As shown in FIG. 8A, a thermal oxidation silicon film 21 with a thickness of 500 nm is formed on the surface of the silicon wafer 3a with a mirror surface in a diffusion furnace. Next, a resist pattern is formed on the thermal oxidation silicon film 21 using a photolithographic technique. Then, the thermal oxidation silicon film 21 is removed by etching with the use of buffered hydrofluoric acid (BHF) so that a pattern of the thermal oxidation silicon film 21 is formed as shown in FIG. 8B. Thereafter, as shown in Fig. C, the horn 22 is formed by, for example, crystalline anisotropic etching using 20% TMAH solution with the patterned silicon dioxide film 21 as a mask. Optionally, the bottom surface of the horn 22 may then be protected by an oxide film using a resist spray coating technique, and only the slanted side walls of the horn may be processed by anisotropic etching using a mixed solution of hydrofluoric acid, nitric acid and water to form the slanted side walls in the shape of elliptical cone (i.e., to round the side walls), as shown in FIG. 8D.

After the formation of the horn 22, all of the remaining thermal oxidation silicon film 21 is removed by BHF solution. Then, as shown in FIG. 8E, a thermal oxidation silicon film 3b having a thickness of 500 nm is formed again using a diffusion furnace on the entire surface of the silicon substrate. Then, a resist is applied thereto using a resist spray coating technique, which is one of the resist application techniques for three-dimensional objects. Furthermore, a resist pattern 23 as shown in FIG. 8F is formed on the thermal oxidation silicon film 3b by a photolithographic technique.

Then, as shown in FIG. 8G, metal film stacks are formed on both the front and rear surfaces of the silicon substrate on the silicon dioxide film 3b on which the resist pattern 23 has been formed. In this case, on the front surface thereof, a metal film stack having four layers (3c, 3d, 3e, and 3f) may be formed. Specifically, a Ti or Ti alloy film (specifically, for example, Ti—Ni alloy film) is deposited on the thermal oxidation silicon film 3b as an adhesion layer 3c. Then, an Ni film is deposited as a barrier metal layer 3d, a Ti or Pd film is deposited as a metal layer 3e, and an Ag or Ag alloy film is deposited as a reflection layer 3f. These layers 3c, 3d, 3e and 3f are sequentially formed in order. Further, on the rear surface of the silicon substrate with the silicon dioxide film 3b, on which the resist pattern 23 has been formed, a metal film stack having three layers (3c, 3d, and 3f) may be formed. Specifically, a Ti or Ti alloy film (specifically, for example, Ti—Ni alloy film) is deposited on the thermal oxidation silicon film 3b as an adhesion layer 3c. Then, an Ni film is deposited as a barrier metal layer 3d, and an Ag or Ag alloy film is deposited as a reflection layer 3f. The layers 3c, 3d and 3f are sequentially formed. The Ti or Pd film serving as the metal layer 3e may also be deposited on the rear surface (between the layers 3d and 3f). However, in terms of its function, it may be deposited only on the front surface. When the Ti film is used as the metal layer 3e, there is no need to use additional materials or add specific facilities because of the Ti adhesion layer 3c, while the heat resistance and the bonding performance during wire-bonding can be enhanced. This can improve the cost performance. Furthermore, it is preferable to form the adhesion layer 3c, the barrier metal layer 3d, the metal layer 3e, and the reflection layer 3f as thin as possible in view of tact time and cost effectiveness.

It is assumed that the metal layer 3e of Ti or Pd film contributes to the heat resistance because it can effectively prevent Ag aggregation. Namely, a thin film formed by sputtering may contain many atomic vacancies and lattice defects and accordingly, atomic diffusion may be likely to occur under these situations. Ag is likely to be diffused due to heating as compared with Au, which is a chemically stable metal. Accordingly, Ag may aggregate through the lattice defects as a predominant diffusion route, thereby coarsening the crystal grains. Coarsened crystal grains may increase the surface roughness of the Ag layer, thereby resulting in the deterioration of reflectance due to heating. The mechanism is assumed as follows: Ti or Pd is deposited as a foundation for the Ag alloy film, and Ti or Pd may exist in the lattice defects or boundary of crystal grains as a diffusion route in a pinpoint manner, to provide a pinning effect for the atomic diffusion of Ag. This may suppress the aggregation of Ag.

As discussed above, the Ti or Pd metal layer 3e can function as an Ag aggregation suppression layer. The metal layer 3e serving as an Ag aggregation suppression layer is not required to completely cover the barrier metal layer 3d and the reflection layer 3f. That is, it may be sufficient for the metal layer 3e to be located at discrete points between the barrier metal layer 3d and the reflection layer 3f (e.g., scattered between the metal layer 3d and the reflection layer 3f) to serve as an Ag aggregation suppression layer. In addition, the metal layer 3e has a thickness sufficient to provide the effect of preventing the aggregation.

When the metal layer 3e serving as an Ag aggregation suppression layer is made of Ti, the thickness thereof is preferably in the range of 0.35 to 200 nm because if the layer is too thick it may reduce the initial reflectance of the metal film 5. On the other hand, when the metal layer 3e serving as an Ag aggregation suppression layer is made of Pd, the initial reflectance of the metal film 5 is not reduced even when the thickness of the Pd layer is 1000 nm. Taking time tact and costs thereof into consideration, the thickness of the metal layer 3e made of Pd is preferably in the range of 1 to 1000 nm.

Furthermore, it is conceivable that the metal layer 3e can contribute the improvement of the wire bonding performance based on its effect for preventing Ni atom diffusion. It is considered that the Ti or Pd metal layer 3e can suppress the aggregation of Ag and at the same time can suppress the Ni atom diffusion from the Ni barrier metal layer 3d to the surface of the reflection layer 3f, to thereby provide an effect of preventing the Ni atom diffusion. In order to prevent the Ni atom diffusion, the metal layer 3e is not required to completely cover the barrier metal layer 3d and the reflection layer 3f. It may be sufficient for the metal layer 3e to be located at discrete points between the barrier metal layer 3d and the reflection layer 3f (e.g., scattered between the metal layer 3d and the reflection layer 3f). The mechanism is assumed as follows: when the metal layer 3e completely covers the barrier metal layer 3d, the metal layer 3e serves as a barrier layer and blocks the Ni diffusion by a barrier effect; and when the metal layer 3e does not completely cover the barrier metal layer 3d, but rather is present at discrete points, or is scattered, on the barrier metal layer 3d, Ti or Pd may exist in the lattice defects or boundary of crystal grains as a diffusion route in a pinpoint manner, to provide a pinning effect for the atomic diffusion of Ni.

After the adhesion layer 3c, the barrier metal layer 3d, the metal layer 3e, and the reflection layer 3f are formed, the metal film stack (3c, 3d, 3e, and 3f) of four layers as shown in FIG. 8H are then lifted-off to fabricate an electrode pattern that also serves as a reflection film of the semiconductor light emitting device. In the example shown in FIG. 8H, an embodiment is shown in which patterning of an electrode is achieved by the lift-off technique. However, the present invention is not limited thereto, and the patterning of the electrode may be achieved by wet etching using acid and/or alkaline solutions, by dry etching such as RIE to pattern the electrode.

Then, a semiconductor light emitting element 4 such as an LED chip is placed and wire-bonded to the silicon substrate having the electrode pattern, as shown in FIG. 9A. The components are electrically connected via wire bonding 25. Alternatively, as shown in FIG. 9B, the semiconductor light emitting element 4 may be electrically connected to the substrate having the electrode pattern via bumps of the substrate to complete the semiconductor light emitting device. For example, a blue semiconductor light emitting element is bonded, and then, the inside of the horn is filled with a transparent resin material 26 in which granular phosphors are dispersed, as shown in Fig. C. Thus, a white semiconductor light emitting device is completed.

Hereinafter, a description will now be given of examples in accordance with the present invention.

### FIRST EXAMPLE

In the first example, a metal film 5 was deposited on a flat silicon substrate with an oxide film. Its reflectance was measured before and after a heat aging test.

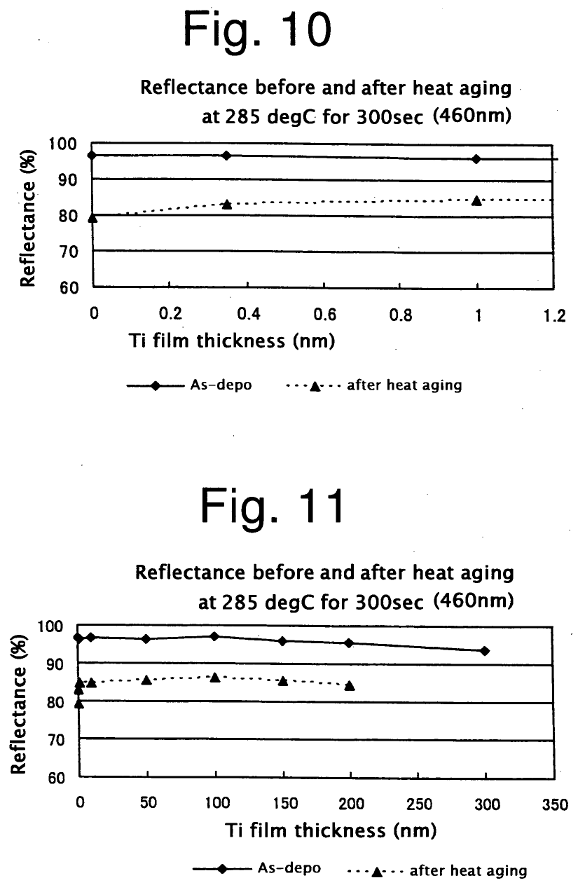

Specifically, the films were deposited on the silicon substrate with an oxide film under the following deposition conditions. A Ti film serving as an adhesion layer 3c was formed with an argon pressure of 1 Pa and a DC output of 1 kW to have a thickness of 75 nm. A Ni film serving as a barrier metal layer 3d was formed with an argon pressure of 0.2 Pa and a DC output of 1 kW to have a thickness of 250 nm. A Ti film serving as a metal layer 3e was formed with an argon pressure of 0.2 Pa and a DC output of 1 kW to have a thickness of from 0.35 to 300 nm (in particular, samples were prepared having the Ti film at thicknesses indicated by the data points in FIGS. 10 and 11, including 0.35 nm, 1 nm, 50 nm, 100 nm, 150 nm, 200 nm and 300 nm). (A control sample without a metal layer 3e was also prepared and is indicated by a Ti thickness of 0 in FIGS. 10 and 11). An Ag alloy film (Ag, 0.85 at. % Bi, and 1.00 at. % Au) serving as a reflection layer 3f was formed with an argon pressure of 0.2 Pa and a DC output of 500 W to have a thickness of 300 nm. In this manner, a metal film stack 5 of four layers (3c, 3d, 3e, and 3f) was fabricated. The heat aging test was performed by placing a deposited sample on a hot plate at normal atmosphere and at 285° C. for 300 seconds.

The reflectance at the wavelength of 460 nm was measured before and after heating. FIGS. 10 and 11 are graphs showing the relationship between the reflectance and the Ti thickness. FIG. 10 shows a very thin range of the Ti thickness of 0 to 1 nm while FIG. 11 shows a thicker range of the Ti thickness of 0 to 300 nm.

When the Ti metal layer 3e having a thickness in the range of from 0.35 nm to 200 nm was deposited between the Ni barrier metal layer 3d and the Ag alloy reflection layer 3f, the initial reflectance before heating was not reduced as compared with the sample without the Ti metal layer 3e. However, the initial reflectance of the sample with the Ti metal layer 3e of 300 nm was reduced. On the other hand, when the Ti metal layer 3e in the range of from 0.35 nm to 200 nm was inserted, the deterioration of reflectance after heating at 285° C. for 300 seconds was suppressed, and the improvement in heat resistance was confirmed.

### SECOND EXAMPLE

In the second example, a metal film 5 was deposited on a flat silicon substrate with an oxide film. Its reflectance was measured before and after the heat aging test.

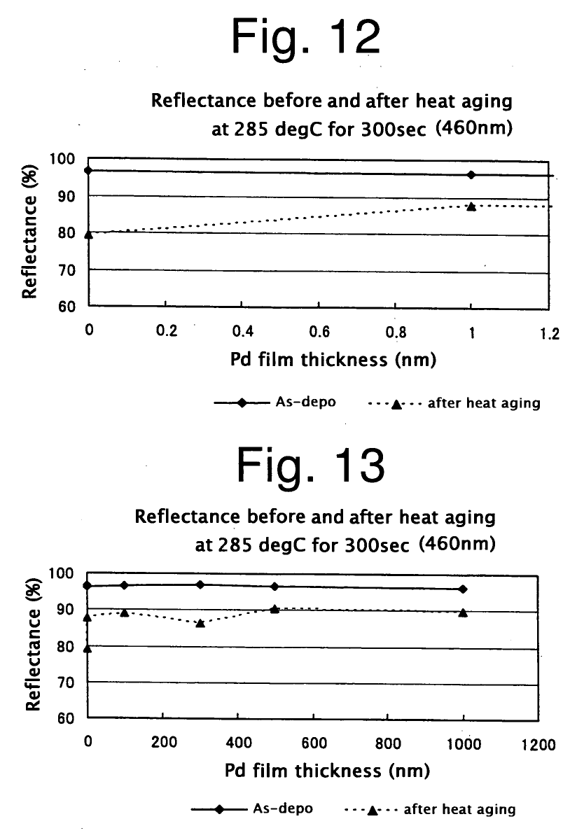

Specifically, the films were deposited on the silicon substrate with an oxide film under the following deposition conditions. A Ti film serving as an adhesion layer 3c was formed with an argon pressure of 1 Pa and a DC output of 1 kW to have a thickness of 75 nm. A Ni film serving as a barrier metal layer 3d was formed with an argon pressure of 0.2 Pa and a DC output of 1 kW to have a thickness of 250 nm. A Pd film serving as a metal layer 3e was formed with an argon pressure of 0.2 Pa and a DC output of 500 W to have a thickness of from 1 to 1000 nm (in particular, samples were prepared having the Pd film at thicknesses indicated by the data points in FIGS. 12 and 13, including 1 nm, 100 nm, 300 nm, 500 nm and 1000 nm). (A control sample without a metal layer 3e was also prepared and is indicated by a Pd thickness of 0 in FIGS. 12 and 13). An Ag alloy film (Ag, 0.85 at. % Bi, and 1.00 at. % Au) serving as a reflection layer 3f was formed with an argon pressure of 0.2 Pa and a DC output of 500 W to have a thickness of 300 nm. In this manner, a metal film stack 5 of four layers (3c, 3d, 3e, and 3f) was fabricated. The heat aging test was performed by placing a deposited sample on a hot plate at normal atmosphere and 285° C. for 300 seconds.

The reflectance at the wavelength of 460 nm was measured before and after heating. FIGS. 12 and 13 are graphs showing the relationship between the reflectance and the Pd thickness. FIG. 12 shows a very thin range of the Pd thickness of 0 to 1 nm while FIG. 13 shows a thicker range of the Pd thickness of 0 to 300 nm.

When the Pd metal layer 3e having a thickness of 1 nm to 1000 nm was deposited between the Ni barrier metal layer 3d and the Ag alloy reflection layer 3f, the initial reflectance before heating was not reduced as compared with the sample without the Pd metal layer 3e. On the other hand, when the Pd metal layer 3e was inserted, the deterioration of reflectance after heating at 285° C. for 300 seconds was suppressed, and the improvement in heat resistance was confirmed.

The Pd metal layer is more effective in improving heat resistance than the Ti metal layer. Furthermore, increasing the thickness of the Pd metal layer does not reduce the initial reflectance as compared to increasing the thickness of the Ti film (to, for example, 300 nm). Accordingly, the Pd metal layer may be preferred as an Ag aggregation suppression layer.

### THIRD EXAMPLE

In the third example, a metal film was deposited on a flat silicon substrate with an oxide film. The substrate was then wire-bonded and subjected to a pulling-strength test.

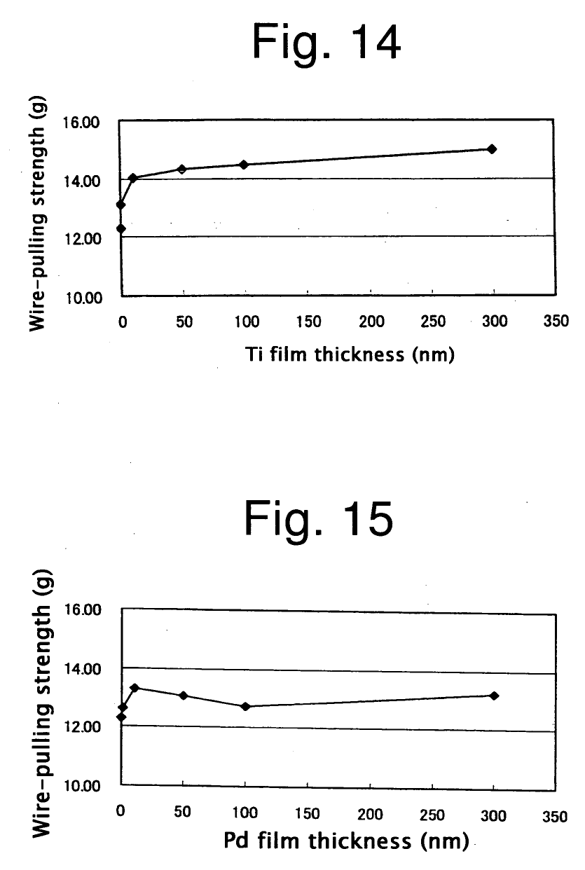

Specifically, the films were deposited on the silicon substrate with an oxide film under the following deposition conditions. A Ti film serving as an adhesion layer 3c was formed with an argon pressure of 1 Pa and a DC output of 1 kW to have a thickness of 75 nm. A Ni film serving as a barrier metal layer 3d was formed with an argon pressure of 0.2 Pa and a DC output of 1 kW to have a thickness of 250 nm. A Ti film serving as a metal layer 3e was formed with an argon pressure of 0.2 Pa and a DC output of 1 kW to have a thickness of from 0.35 to 300 nm (in particular, samples were prepared having the Ti film at thicknesses indicated by the data points in FIG. 14, including 0.35 nm, 20 nm, 50 nm, 100 nm and 300 nm). (A control sample without a metal layer 3e was also prepared and is indicated by a Ti thickness of 0 in FIG. 14). An Ag alloy film (Ag, 0.85 at. % Bi, and 1.00 at. % Au) serving as a reflection layer 3f was formed with an argon pressure of 0.2 Pa and a DC output of 500 W to have a thickness of 300 nm. In this manner, a metal film stack 5 of four layers (3c, 3d, 3e, and 3f) was fabricated. In this example, an Au wire with a diameter of 30 μm was used for bonding. The 1st bonding and 2nd bonding were performed on the flat substrate without any chip mounted thereon. Further, the loop height of the wire was 300 μm, the loop width of the wire was 2000 μm, and the substrate temperature during the test was 120° C.

FIG. 14 is a graph showing the result of the wire-pulling strength test. As is clear from the results shown in FIG. 14, The provision of the Ti metal layer 3e could improve the wire-pulling strength. This effect could be confirmed even when the thickness of the Ti metal layer 3e was very thin, i.e., 0.35 nm. Furthermore, the wire-pulling strength was increased as the Ti metal layer 3e was made thicker.

### FOURTH EXAMPLE

In the fourth example, a metal film was deposited on a flat silicon substrate with an oxide film. The substrate was then wire-bonded and subjected to the pulling-strength test.

Specifically, the films were deposited on the silicon substrate with an oxide film under the following deposition conditions. A Ti film serving as an Adhesion layer 3c was formed with an argon pressure of 1 Pa and a DC output of 1 kW to have a thickness of 75 nm. A Ni film serving as a barrier metal layer 3d was formed with an argon pressure of 0.2 Pa and a DC output of 1 kW to have a thickness of 250 nm. A Pd film serving as a metal layer 3e was formed with an argon pressure of 0.2 Pa and a DC output of 1 kW to have a thickness of from 0.1 to 300 nm (in particular, samples were prepared having the Pd film at thicknesses indicated by the data points in FIG. 15, including 0.35 nm, 20 nm, 50 nm, 100 nm and 300 nm). (A control sample without a metal layer 3e was also prepared and is indicated by a Pd thickness of 0 in FIG. 15). An Ag alloy film (Ag, 0.85 at. % Bi, and 1.00 at. % Au) serving as a reflection layer 3f was formed with an argon pressure of 1.0 Pa and a DC output of 500 W to have a thickness of 300 nm. In this manner, a metal film stack 5 of four layers (3c, 3d, 3e, and 3f) was fabricated. In this example, an Au wire with a diameter of 30 μm was used for bonding. The 1st bonding and 2nd bonding were performed on the flat substrate without any chip mounted thereon. Further, the loop height of the wire was 300 μm, the loop width of the wire was 2000 μm, and the substrate temperature during the test was 120° C.

FIG. 15 is a graph showing the result of the wire-pulling strength test. As is clear from the results shown in FIG. 15, The provision of the Pd metal layer 3e could improve the wire-pulling strength. This effect could be confirmed even when the thickness of the Pd metal layer 3e was very thin, i.e., 0.1 nm. However, the degree of improvement by the provision of Pd metal layer was not so high as compared with the case of provision of Ti metal layer.

A detailed description will now be made of an example in which an Ag alloy layer is deposited as the reflection layer 3f. In this instance, an Ag—Bi alloy is exemplified as the Ag alloy.

First, two samples of Ag—Bi (0.07 at. % and 0.14 at. %)-Nd (neodymium) film (film thickness of 0.1 μm) were subjected to a durability test. Note that the two samples each contain 0.2 at. % Nd and 99 at. % or more Ag. The measurements were performed using an n&k analyzer of n&k Technology Inc. (USA) based on a patented technology, an n&k method (see A. R. Furouhi and I. Bloomer, Method and Apparatus for Determining Optical Constants of Materials; U.S. Pat. No. 4,905,170, the entire contents of which are incorporated herein by reference; 1990)

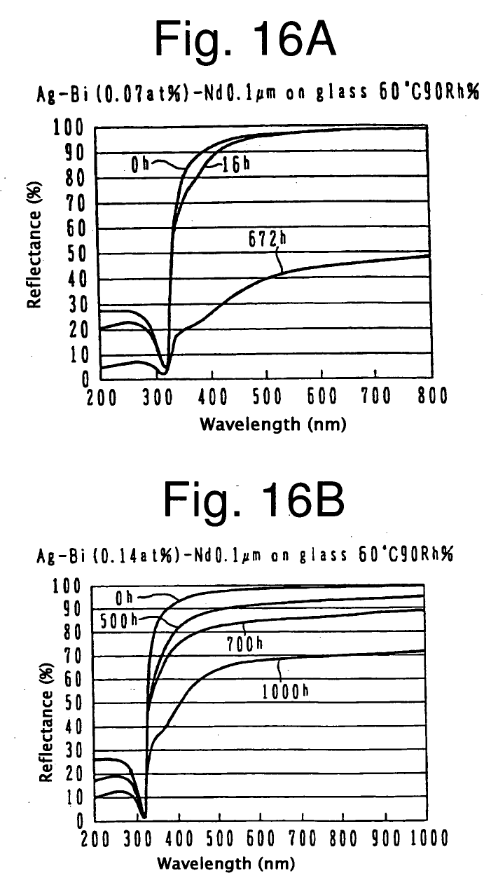

FIG. 16A is a graph showing vertical reflectances of Ag—Bi(0.07 at. %)-Nd relative to a lapsed time, and FIG. 16B is a graph showing vertical reflectances of Ag—Bi(0.14 at. %)-Nd relative to a lapsed time. As is clear from the results shown in FIGS. 16A and 16B, it has been revealed that the larger the Bi content in Ag becomes, the better the durability of the layer becomes.

In order to find the preferred content range of Bi, the following experiment was performed. On a glass substrate, the following five types of films with a thickness of 0.1 μm were deposited by sputtering using various target materials.
Sample A: Ag—Bi—Nd alloy film (Bi atomic %=0.07)
Sample B: Ag—Bi—Nd alloy film (Bi atomic %=0.14)
Sample C: Ti/Ag—Bi—Nd alloy film (Bi atomic %=0.14, Ti film thickness=0.05 μm)
Sample D: Ti/Ag—Bi—Nd alloy film (Bi atomic %=0.22, Ti film thickness=0.05 μm)
Sample E: Ti/Ag—Bi—Nd alloy film (Bi atomic %=0.24, Ti film thickness=0.05 μm)

Initial vertical reflectances of the five samples with the five types of alloy films were measured using an n&k analyzer.

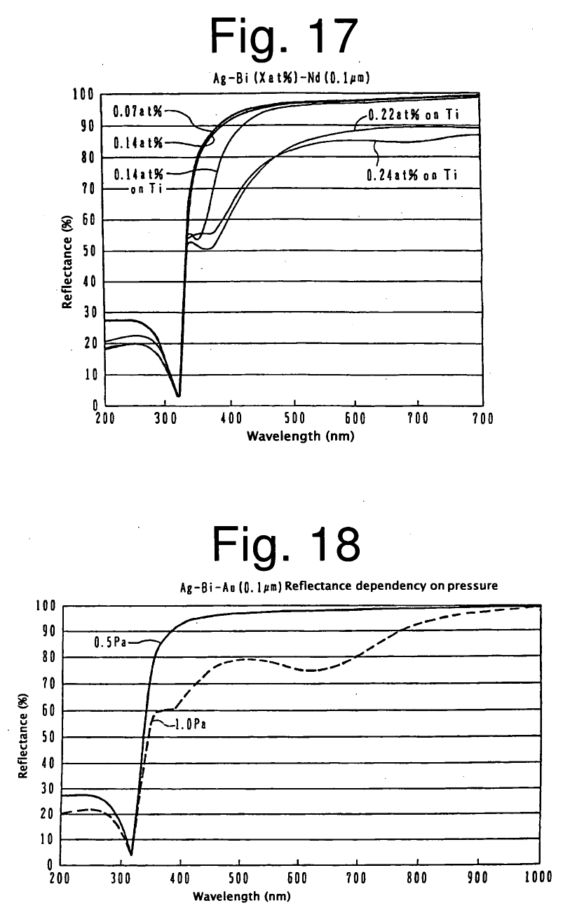

FIG. 17 is a graph showing initial vertical reflectances of the above-described samples. As shown in FIG. 17, as the Bi content increases, the initial vertical reflectance lowers. It has been revealed that the Bi content is preferably set to 0.14 at. % or lower in order to use the alloy film as a reflection film.

It has been found from the above two types of experiments that when the Bi content is set in the range of from 0.07 at. % to 0.14 at. %, the initial reflectance can be maintained as high as practically usable as an LED package and the durability can be ensured. It is considered that the Bi content in the Ag alloy layer of a semiconductor light emitting device is preferably in the range of from 0.05 at. % to 0.15 at. %.

In the Ag—Bi alloy, at least one of Au, Pd, Pt, and Cu is preferably added as an additional element. A total addition amount is preferably in the range of from 0.5 to 5.0 at. %, and more preferably in the range of from 1.0 to 2.0 at. %. Alternatively, or additionally, as the alternative element, any one of additional elements Nd and other rare earth elements may be added. The addition amount of Nd, for example, is preferably in the range of from 0.1 to 1.0 at. %, and more preferably in the range of from 0.1 to 0.5 at. %. When the added amount is greater than the above range, the initial reflectance and the electric resistance may be reduced. Note that the performances exhibited desired results when adding at least one of Au, Pd, Cu, Pt and Nd at an atomic % larger than that of Bi in the Ag—Bi alloy containing Bi of the above preferred range. In this case, the Ag content is 94 at. % or more.

FIG. 18 is a graph showing a dependency of a reflectance of an Ag—Bi alloy on the pressure during film deposition. The graph as shown in FIG. 18 shows the case where an Ag—Bi—Au film (film thickness of 0.1 μm) is formed on a silicon substrate. The vertical axis represents a reflectance and the horizontal axis represents a wavelength of light. At a pressure of 0.5 Pa during deposition, a reflectance is near 100% in the visible range, whereas at 1 Pa, a reflectance lowers as the wavelength shortens, even in the visible range. It is therefore preferable that the pressure during film formation be lower than 1 Pa.

Accordingly, it is preferable to deposit an Ag alloy as a reflection layer under the above mentioned condition. A film thickness is preferably in the range of from 0.1 μm to 0.6 μm.

As described above, in accordance with the present invention, the Ti or Pd metal layer 3e is provided between the barrier metal layer 3d and the reflection layer 3f. This structure can prevent the reflectance of the metal layer 5 (reflection layer 3f) from lowering due to heat aging. In addition, when the barrier metal layer is made of Ni, the Ni of the barrier metal layer 3d may be diffused into the reflection layer 3f during die-bonding of the semiconductor light emitting element (for example, LED element), which lowers the wire-bonding performance. However, the structure in accordance with the present invention can prevent the lowering of the wire-bonding performance, due to the presence of the metal layer 3e. Accordingly, LED packages that are practically stable can be fabricated and supplied in accordance with the present invention.

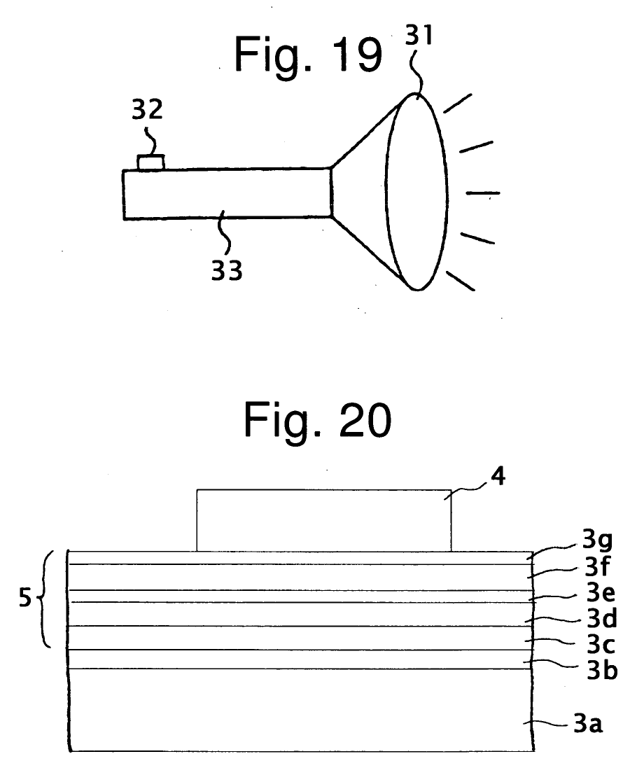

The LED packages fabricated in accordance with the present invention can be used in various light emitting apparatuses, one of which is the light shown in FIG. 19. FIG. 19 is a diagram showing a usage of the LED package, wherein the LED package is mounted in an LED light emitting body 31 and the switch 32 can control the power supply to the LED package. A user can grasp the handle 33 to direct the light emitted from the LED light emitting body 31 in a desired direction.

The present invention is not limited to the embodiments described above.

For example, the reflection layer 3f may be composed of a plurality of reflection areas which are electrically connected to the semiconductor light emitting element 4 to achieve a semiconductor light emitting device of RGB mixed color type.

Furthermore, though the semiconductor light emitting element 4 is mounted on the reflection layer 3f in the embodiments described above, the present invention is not limited thereto. For example, an insulating material may be arranged on the semiconductor light emitting element 4 and the surrounding electrodes can be connected with the use of wires. That is, in the embodiments described above, the reflection layer 3f can serve as a reflection film and an electrode, but the reflection layer may serve only as a reflection film.

Moreover, the horn formed in the silicon substrate 3a may be rounded or may not. That is, as noted above, the step shown in FIG. 8D is optional.

Furthermore, as shown in FIG. 20, a Ti coating layer 3g that is thinner than the reflection layer 3f may be deposited on the reflection layer 3f. In this case, the Ti coating layer 3g may not only be Ti, but also be made of Ti oxide, Ti nitride, Ti carbide, or the like (for example, TiOₓ, TiOₓN_{y}, and the like). The thickness of the Ti coating layer 3g may be in the range of 0.35 nm to 2 nm.

When such a Ti coating layer 3g thinner than the reflection layer 3f is provided, the Ti coating layer 3g does not affect the reflectance by the reflection layer 3f of the light from the semiconductor light emitting element 4. That is, the transparency of the Ti coating layer 3g is maintained to be high and may not lower the reflectance of the reflection layer 3f. Furthermore, the Ti coating layer 3g may have a high conductivity (low resistance) to serve as an electrode and may function as a protection layer for the reflection layer 3f. In other words, the Ti coating layer 3g can function as a surface protection layer for preventing the reflectance of the reflection layer 3f from being lowered due to sulfurization and/or heat.

When an Ag or Ag alloy is used as the material for the reflection layer 3f, the reflectance thereof may be lowered due to sulfurization and/or heat without any protection layer. When the Ti coating layer 3g is provided, it can prevent the reflectance of the Ag or Ag alloy film from being lowered due to sulfurization and/or heat. When Al is used as the material for the reflection layer 3f, although the degree by which the reflectance of Al is lowered due to sulfurization and/or heat is not as high as with the Ag reflection layer 3f, the Ti coating layer 3g can prevent the reflectance of the Al film from being lowered due to sulfurization and/or heat.

In the example shown in FIG. 20, the Ti coating layer 3g, the reflection layer 3f, and the semiconductor light emitting element 4 can be electrically connected with each other. Then, the reflection layer 3f can function as a reflection film and as an electrode. Specifically, for example, the semiconductor light emitting element 4 can be electrically connected to the reflection layer 3f via the Ti coating layer 3g. In this case, the semiconductor light emitting element 4 is die-bonded or wire-bonded to the Ti coating layer 3g. In a specific example, a semiconductor light emitting element 4 having a rear electrode can be directly die-bonded to the Ti coating layer 3f. Alternatively, when a part of the Ti coating layer 3g has an opening, the semiconductor light emitting element 4 can be directly bonded (directly electrically connected) to the reflection layer 3f without the Ti coating layer 3g interposed therebetween.

The present invention can be applied to a monochromatic LED, or a white LED with the help of excited phosphor for general purpose use, for a strobe scopic lamp, or for backlight, a white LED of RGB mixed color type, an LED with a dimmer circuit, a photosensor having both transmitting and receiving functions, a photo interrupter, a photo coupler, and the like.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents. All related art references described above are hereby incorporated in their entireties by reference.

What is claimed is:

1. A semiconductor light emitting device, comprising:
a substrate;
a metal film deposited on the substrate; and
a semiconductor light emitting element,
wherein the metal film comprises:
a barrier metal layer configured to prevent a predetermined material from being diffused into the substrate;
a metal layer consisting essentially of Ti or Pd; and
a reflection layer configured to reflect light emitted from the semiconductor light emitting element,
wherein the barrier metal layer, the metal layer, and the reflection layer are deposited in this order from the substrate.

2. The semiconductor light emitting device according to claim 1, wherein the barrier metal layer consists essentially of Ni.

3. The semiconductor light emitting device according to claim 1, wherein the reflection layer consists essentially of Ag or an Ag alloy.

4. The semiconductor light emitting device according to claim,2, wherein the reflection layer consists essentially of Ag or an Ag alloy.

5. The semiconductor light emitting device according to claim 3, wherein the Ag alloy contains at least one element selected from the group consisting of Bi, At, Pd, Cu, Pt, and Nd.

6. The semiconductor light emitting device according to claim 4, wherein the Ag alloy contains at least one element selected from the group consisting of Bi, At, Pd, Cu, Pt, and Nd.

7. The semiconductor light emitting device according to claim 1, wherein the barrier metal layer consists essentially of Ni, the reflection layer consists essentially of Ag or an Ag alloy, and the metal layer consists essentially of Ti and has a thickness in a range of from 0.35 nm to 200 nm.

8. The semiconductor light emitting device according to claim 1, wherein the barrier metal layer consists essentially of Ni, the reflection layer consists essentially of Ag or an Ag alloy, and the metal layer consists essentially of Pd and has a thickness in a range of from 1 nm to 1000 nm.

9. The semiconductor light emitting device according to claim 1, wherein the substrate has a surface defined by a bottom surface having a (100) plane and slanted side walls having a (111) plane, and the metal film is formed at least on the bottom surface and the slanted side walls.

10. An LED package, comprising:
a housing;
a lead frame provided along part of the housing and having a pair of leads; and
a semiconductor light emitting device comprising:
a substrate;
a metal film deposited on the substrate; and
a semiconductor light emitting element,
wherein the metal film comprises:
a barrier metal layer configured to prevent a predetermined material from being diffused into the substrate;
a metal layer consisting essentially of Ti or Pd; and
a reflection layer configured to reflect light emitted from the semiconductor light emitting element,
wherein the barrier metal layer, the metal layer, the reflection layer are deposited in this order from the substrate, and
wherein the semiconductor light emitting element is mounted on at least part of the lead frame and is electrically connected to the pair of leads.

11. The LED package according to claim 10, wherein the housing has a recess in which the semiconductor light emitting device is mounted, and a sealing resin is filled in the recess to seal the semiconductor light emitting device.

12. The LED package according to claim 10, wherein the sealing resin contains a wavelength converting material.

13. The LED package according to claim 10, wherein the barrier metal layer consists essentially of Ni.

14. The LED package according to claim 10, wherein the reflection layer consists essentially of Ag or an Ag alloy.

15. The LED package according to claim 13, wherein the reflection layer consists essentially of Ag or an Ag alloy.

16. The LED package according to claim 14, wherein the Ag alloy contains at least one element selected from the group consisting of Bi, At, Pd, Cu, Pt, and Nd.

17. The LED package according to claim 15, wherein the Ag alloy contains at least one element selected from the group consisting of Bi, At, Pd, Cu, Pt, and Nd.

18. The LED package according to claim 10, wherein the barrier metal layer consists essentially of Ni, the reflection layer consists essentially of Ag or an Ag alloy, and the metal layer consists essentially of Ti and has a thickness in a range of from 0.35 nm to 200 nm.

19. LED package according to claim 10, wherein the barrier metal layer consists essentially of Ni, the reflection layer consists essentially of Ag or an Ag alloy, and the metal layer consists essentially of Pd and has a thickness in a range of from 1 nm to 1000 nm.

20. LED package according to claim 10, wherein the substrate has a surface defined by a bottom surface having a (100) plane and slanted side walls having a (111) plane, and the metal film is formed at least on the bottom surface and the slanted side walls.

21. A method for fabricating a semiconductor light emitting device, comprising:
forming a barrier metal layer made of Ni on a silicon substrate;
forming a metal layer consisting essentially of Ti or Pd on the barrier metal layer;
forming a reflection layer made of Ag or an Ag alloy on the metal layer; and
electrically connecting a semiconductor light emitting element to the reflection layer.
